(19) United States
(12) Patent Application Publication
(10) Pub. No.: US 2002/0006487 A1
(43) Pub. Date: Jan. 17, 2002

(54) Transmission barrier layer for polymers and containers

(76) Inventors: Paul J. O'Connor, Midland, MI (US); Ing-Feng Hu, Midland, MI (US)

Correspondence Address: THE DOW CHEMICAL COMPANY, INTELLECTUAL PROPERTY SECTION, P. O. BOX 1967, MIDLAND, MI, 48641-1967, US

(21) Appl. No.: 09/873,621

(22) Filed: Jun. 4, 2001

Related U.S. Application Data
(60) Provisional application No. 60/209,540, filed on Jun. 6, 2000.

(51) Int. Cl. B29D 22/00; C23C 16/00; B32B 27/06

(52) U.S. Cl. 428/35.7; 427/569; 428/451

(57) ABSTRACT

A barrier to diffusion of gas through polymers by means of plasma generated coating on polymeric substrates. The coating is suitable for application on planar polymeric substrates such as sheet or film. The coating is suitable for application on three-dimensional polymeric substrates, such as polymeric containers, or bottles.

### CROSS-REFERENCE STATEMENT

This application claims the benefit of U.S. Provisional Application No. 60/209,540, filed Jun. 6, 2000.

This invention concerns plastic films and containers having enhanced the barrier performance supplied by coatings to the surface of the container or film. The coated containers and films may be readily recycled.

### BACKGROUND OF THE INVENTION

Polymer containers currently comprise a large and growing segment of the food beverage industry. Plastic containers are lightweight, inexpensive, non-breakable, transparent, and readily manufactured. Universal acceptance of plastic containers is limited by the greater permeability of plastic containers to water, oxygen, carbon dioxide and other gases and vapors as compared to glass and metal containers.

Pressurized beverage containers comprise a large market worldwide. Polyethylene terephthalate (PET) is the predominant polymer for beverage containers. Beverage containers used for carbonated beverages have a shelf life limited by the loss of CO₂. Oxygen ingress also adversely impacts beverage shelf life, such as the flavor of beer. The shelf life of small containers is aggravated by the ratio of surface to volume. Improved barrier properties will facilitate smaller beverage containers having acceptable shelf life and extend the shelf life of containers having smaller ratios of surface to volume. The utility of polymers as containers generally can be enhanced by providing improved barrier properties to small sized organic molecules, such as plasticizers or oligomers, which may migrate through the polymer, such as those organic molecules having molecular weights less than 200, especially less than 150 and smaller.

An effective coating on plastic bottles must have suitable barrier properties after the bottles have experienced flexure and elongation. Coatings for pressurized beverage containers should be capable of biaxial stretch while maintaining effective barrier properties. If the coating is on the external surface of the container, the coating should also resist weathering, scratches and abrasion in normal handling in addition to maintaining an effective gas barrier throughout the useful life of the container.

Coatings of silicon oxide provide an effective barrier to gas transmission. However, for polymeric films and polymeric containers of a film-like thickness, polymer coatings of silicon have insufficient flexibility to form an effective barrier to gas transmission. WO 98/40531 suggests that for containers coated with SiOx where x is from 1.7 to 2.0, pressurized to 414 kPa, that a 25 percent to 100 percent improvement over the transmission barrier provided by the polymer is adequate for limited shelf life extension of a carbonated beverage. The thickness of the coating is not discussed. Whereas the requirements for packaging beer in plastic containers requires a seven-fold increase of CO₂ barrier and a twenty-fold increase of oxygen barrier than provided by PET bottles of commercial thickness (39 g PET for 500 ml bottle).

Similarly, U.S. Pat. No. 5,702,770 ('770 reference) to Becton Dickinson Company reports SiOx coating on rigid PET substrates. O₂ barrier properties from 1.3 to 1.6 fold increase over the barrier provided by PET are reported. It should be noted that the wall thickness in the '770 reference is sufficient to remain substantially rigid when subjected to a vacuum.

### SUMMARY OF THE INVENTION

An object of the present invention is to provide a coating for a container such as a polymer bottle, particularly the non-refillable bottles used for carbonated beverages and oxygen sensitive contents in polymeric bottles and other plastic containers, such as beer, juices, teas, carbonated soft drinks, processed foods, medicines, and blood. A further advantage of a container incorporating a coating according to the present invention is the opportunity to reduce the wall thickness of the container while maintaining a suitable barrier to the permeation of odorants, flavorants, ingredients, gas and water vapor. Permeation in this context includes the transmission into the container or out of the container.

For some applications, consumers prefer polymer containers having a clear appearance such as those manufactured from clear or colorless PET. Another object of the invention is to provide a barrier to the permeation of gas without adversely effecting the clear appearance of a polymer container.

Applicants have surprisingly found that plasma coatings of SiOx incorporating organics (e.g., SiOxCyHz) serve as an underlayer, tie-layer, or primer for application of a dense barrier layer. The system provides an oxygen transmission rate (OTR) of <0.02 cc/m2-day-atm. This is a greater than 50-fold barrier improvement compared to an uncoated PET polymer substrate of 175 microns thick (as in a commercial PET bottle). Moreover, the barrier is remarkably stable after strain such as would be encountered by a pressurized beverage container. The barrier demonstrates good adhesion to the polymeric substrate with no evident detachment. There can be provided thereby a polymeric (plastic) container having a barrier to permeation similar to glass.

Plasma coatings of SiOx incorporating organics (e.g., SiOxCyHz) are taught by U.S. Pat. No. 5,718, 967, incorporated herein by reference. Further, it is disclosed that such coatings protect polymeric substrates against solvents and abrasion.

### DESCRIPTION OF PREFERRED EMBODIMENTS

In one embodiment, the invention is a polymeric container having a plasma-polymerized surface of an organic-containing layer of the formula SiOxCyHz. The variables of the formula having ranges: x is from about 1.0 to 2.4, y is from about 0.2 to 2.4. The variable z may have a lower value of 0.7, preferably 0.2, more preferably 0.05, still another lower value would be approaching zero, or zero itself. The variable z may have an upper value of from 4, preferably 2, more preferably 1. The aforesaid organic-containing layer lies between the surface of the polymeric substrate and a further plasma-generated high-barrier layer.

In another embodiment, the invention is a polymeric substrate having a surface and a barrier thereon having an oxygen transmission rate less than 0.75 cc/m² -day-atm.

The dense, high-barrier layer is also generated from a plasma of an organosilane containing compound which may be the same, or different from the organosilane compound which forms the carbon-containing layer. In addition to the organosilane, the dense, high-barrier layer is formed from a plasma which also contains an oxidizer. The high-barrier layer, which is generated from an organosilane plasma, comprises SiOx. It has been suggested in the literature that SiOx from an organosilane and oxidizer plasma creates a structure in which the variable x preferably has a value of from about 1.7 to about 2.2; that is, SiO_{1.7-2.2} with some incorporation of organic components, as taught in JP 6-99536; JP 8-281861 A.

In another embodiment, the plasma-formed barrier system may be a continuum of a plasma deposited coating having a composition which varies from the formula SiOxCyHz at the interface between the plasma layer and the polymeric container's original surface to SiOx at what has become the new surface of the container. The continuum is conveniently formed by initiating a plasma in the absence of an oxidizing compound, then adding an oxidizing compound to the plasma, finally at a concentration in sufficient quantity to essentially oxidize the precursor monomer. Alternatively, a barrier system having a continuum of composition from the substrate interface may form a dense, high-barrier portion by increasing the power density and/or the plasma density without a change of oxidizing content. Further, a combination of oxygen increase and increased power density/plasma density may develop the dense portion of the gradient barrier system.

Suitable organosilane compounds include silane, siloxane or silazane, including: methylsilane, dimethylsilane, trimethylsilane, diethylsilane, propylsilane, phenylsilane, hexamethyldisilane, 1,1,2,2-tetramethyl disilane, bis(trimethylsilyl)methane, bis(dimethylsilyl) methane, hexamethyldisiloxane, vinyl trimethoxy silane, vinyltriethoxy silane, ethylmethoxy silane, ethyltrimethoxy silane, divenyltetramethyldisiloxane, divinylhexamethyltrisiloxane, and trivinylpentamethyltrisiloxane, 1,1,2,2-tetramethyldisiloxane, hexamethyldisiloxane, vinyltrimethylsilane, methyltrimethoxysilane, vinyltrimethoxysilane and hexamethyldisilazane. Preferred silicon compounds are tetramethyldisiloxane, hexamethyldisiloxane, hexamethyldisilazane, tetramethylsilazane, dimethoxydimethylsilane, methyltrimethoxysilane, tetramethoxysilane, methyltriethoxysilane, diethoxydimethylsilane, methyltriethoxysilane, triethoxyvinylsilane, tetraethoxysilane, dimethoxymethylphenylsilane, phenyltrimethoxysilane, 3-glycidoxypropyltrimethoxysilane, diethoxymethylpehnylsilane, tris(2-methoxyethoxy)vinylsilane, phenyltriethoxysilane and dimethoxydiphenylsilane.

Suitable volatile, or volatilizable oxidizers such as O₂, air, N₂O, Cl₂, F₂, H₂O or SO₂ may be included for an oxidized plasma.

Optionally, other gases may be included in the plasma. Air for example may be added to O₂ as a partial diluent. He, N₂, and Ar are suitable gases.

Generation of a plasma of the invention may occur by known methods: electromagnetic radiation of radio frequency, microwave generated plasma, AC current generated plasma as are taught in U.S. Pat. Nos. 5,702,770; 5,718,967, and EP 0 299 754, DC current arc plasma is taught by U.S. Pat. Nos. 6,110,544, all incorporated herein by reference. Magnetic guidance of plasma such as is taught in U.S. Pat. No. 5,900,284 is also incorporated herein by reference. For plasma generated coatings on the inside surface of a container, plasma may be generated within the container similar to the teachings of U.S. Pat. No. 5,565,248 which is limited to inorganic sources of plasma for coatings including silicon. Further, the magnetic guidance of plasma as taught in U.S. Pat. No. 5,900,284 may be wholly within a container, or optionally magnetic guidance and a plasma generating electrode may be wholly within a container. Magnetic guidance of plasma for a barrier coating on the inside surface of a container may also be provided by magnetic guidance wholly outside a container and optionally with plasma generating electrode(s) within the container. Magnetic guidance of plasma for a barrier coating on the inside surface of a container may also be provided by magnetic guidance, partially within a container and partially outside a container. Optionally for the case of magnetic guidance of plasma for a barrier coating on the inside surface of a container, where partial magnetic guidance is provided within the container, a plasma generating electrode may also be included within the container, as may a source for the plasma reactant, a silane.

Condensed-plasma coatings of the present invention surprisingly maintain their barrier properties after strain, yet present the food compatible surface SiOx.

The condensed-plasma coatings of the present invention may be applied on any suitable substrate. Enhanced barrier properties will result when the condensed-plasma coatings of the invention are applied to suitable polymeric substrates including: polyolefins such as polyethylene, polypropylene, poly-4-methylpentene-1, polyvinylchloride, polyethylene napthalate, polycarbonate, polystyrene, polyurethanes, polyesters, polybutadienes, polyamides, polyimides, fluoroplastics such as polytetrafluorethylene and polyvinylidenefluoride, cellulosic resins such as cellulose proprionate, cellulose acetate, cellulose nitrate, acrylics and acrylic copolymers such as acrylonitrile-butadiene-styrene, chemically modified polymers such as hydrogenated polystyrene and polyether sulfones. Because of the thermal limitations of the suitable polymers useful in this invention, it may be advantageous to provide a means of minimizing thermal load on the substrate and/or coating.

The condensed-plasma coating is readily generated on a two-dimensional surface such as a film or sheet, and on a three dimensional surface such as a tube, container or bottle.

Generally plasma is more readily generated under vacuum conditions. Absolute pressures in the chamber where plasma is generated are often less than 100 Torr, preferably less than 500 mTorr and more preferably less than 100 mTorr.

Power density is the value of W/FM where W is an input power applied for plasma generation expressed in J/sec. F is the flow rate of the reactant gases expressed in moles/sec. M is the molecular weight of the reactant in Kg/mol. For a mixture of gases the power density can be calculated from W/ΣFᵢMᵢ where “i” indicates the “i”th gaseous component in the mixture. The power density applied to the plasma is from 10⁶ to 10¹¹ Joules/Kilogram.

### SPECIFIC EMBODIMENTS

### Example 1

A condensed-plasma coating of the invention may be prepared in a vacuum chamber under base-vacuum conditions of 0.5 mTorr. The substrate was polyethylene terphthalate (PET) film having a thickness of 175 μm as may be obtained from DuPont Polyester Films, Wilmington Del, United States of America under the product designation Melinex ST504. The substrate was cleaned by wiping with methylethyl ketone. An organosilane reactant gas of tetramethyldisiloxane (TMDSO) was admitted to the chamber at the rate of 15 standard cubic centimeters per minute (sccm). Plasma was generated using a power of 800 watts operating at a frequency of 110 KHz with an impedance matching network for 45 seconds generating a condensed-plasma deposited on the PET film of about 0.05 μm thickness. The plasma electrode has a structure described in U.S. Pat. No. 5,433,786. 5.3×10⁸ J/kg power density was applied.

### Example 2

On a PET substrate having a coating prepared according to Example 1, a second condensed-plasma layer was formed by adding O₂ at 40 sccm to the vacuum chamber. TMDSO was increased from 15 sccm to 45 sccm linearly over 3 minutes, then held constant for 90 minutes. A condensed-plasma layer of 3.2 μm on the PET substrate resulted. The power density was 1.5×10⁸ J/kg. A further condensed-plasma layer was generated with the original rate of TMDSO and O₂ at 200 sccm with a plasma power of 2700 watts for 3 minutes which generated an additional layer of about 300Å. The power density of this last step was 4.3×10⁸ J/kg. A colorless and clear coating resulted on the substrate.

### Example 3

The barrier properties of PET films generated in Example 2 were measured in 100 percent O₂ 38° C. and 90 percent relative humidity. Uniaxial strain was provided by an INSTRON mechanical testing device.

| | | | Scanning |
|---|---|---|---|
| | | | Electron |
| | | Oxygen | Microscope |
| | Strain History | transmission rate | Examination of |
| | (%) | (cc/m²-day-atm) | Coating Surface |
| Uncoated PET | 0.0 | 10.2 | N.A. |
| Uncoated PET | 2.5 | 10.2 | N.A. |
| Coated PET | 0.0 | <0.015 | no microcracks |
| Coated PET | 1.0 | <0.015 | no microcracks |
| Coated PET | 2.0 | <0.015 | no microcracks |
| Coated PET | 2.5 | <0.015 | no microcracks |
| Coated PET | 3.0 | 0.06 ± 0.06 | no microcracks |
| Coated PET | 4.0 | 0.045 ± 0.045 | no microcracks |
| Coated PET | 5.0 | 0.024 ± 0.03 | no microcracks |

### Example 4

On cleaned PET a plasma is generated under vacuum conditions as in Example 1 using O₂ as the plasma generating gas at 30 sccm. Plasma is generated by a load power of 800 watts for 40 seconds.

The plasma may be generated from air, or mixtures of oxidizing gas and other gas, such as O₂ and He, or O₂ and Ar. Plasma thus generated serves to adhere subsequent plasma layers to the PET substrate. Power density for generation of such plasma ranges from 10⁶ to 10¹⁰ J/kg.

A condensed-plasma layer is then formed by flowing O₂ at 40 sccm to the vacuum chamber and TMDSO is flowed from 15 sccm to 45 sccm linearly over 3 minutes, then held constant for 90 minutes. A condensed-plasma layer of 3.2 μm on the PET substrate results. The power density is 1.5×10⁸ J/kg. A further condensed-plasma layer is generated with the original rate of TMDSO and O₂ at 200 sccm with a plasma power of 2700 watts for 3 minutes. The conditions generate an additional condensed-plasma layer of about 300Å. The power density of this last step is 4.3×10⁸ J/kg. Barrier to oxygen transmission compare favorably with Example 2.

Example 4 may be repeated using, as the pretreatment gas, any of the known oxidizing gases or other surface treating gases.

### Example 5

Plasma coated PET prepared according to Example 2 is ground, extruded to a pre-form, then blow-molded to the form of a beverage container. Enclosed in a vacuum chamber, a plasma is generated within the blow-molded container according to the sequence and energy of Example 1 forming a condensed-plasma layer. The container is tested for oxygen permeability, with good transmission barrier properties.

### Example 6

A container is prepared according to Example 5. The plasma generated is directed using a magnetron consistent with that disclosed in FIG. 6 of U.S. Patent 5,993,598. A clear colorless condensed-plasma coating results. The coated container is tested for oxygen permeability, with uniform good transmission barrier properties comparable to Example 2.

### Example 7

A PET substrate is heated and stretched and then immediately transferred to a vacuum chamber comparable to the conditions of Example 1. Thereafter a coating is applied by flowing TMDSO at 15 sccm and flowing O₂ at 40 sccm to the vacuum chamber. TMDSO is increased from 15 sccm to 45 sccm linearly over 3 minutes, then held constant for 90 minutes. A condensed-plasma layer of 3.2 μm on the PET substrate results. The power density is 1.5×10⁸ J/kg. A further condensed-plasma layer is generated with the original rate of TMDSO and O₂ at 200 sccm with a plasma power of 2700 watts for 3 minutes which generates an additional layer of about 300 Å. The power density of this last step is 4.3×10⁸ J/kg. A clear colorless condensed-plasma coating results on the substrate with uniform good barrier properties, comparable to Example 2.

### Example 8

Example 8a—Three zone coating

A three-dimensional beverage container is placed in a vacuum chamber with a microwave-frequency plasma generating source. The plasma system is designed to generate a plasma substantially in the interior volume of the container. An organosilane reactant gas of tetramethyldisiloxane (TMDSO) is admitted to the container at the rate of 2 sccm. Plasma is generated with an applied microwave power of 100 W for 2 seconds generating a condensed-plasma on the interior surface of the container. A second condensed-plasma zone is formed by adding oxygen at 2 sccm to the container with an applied microwave power of 100 W for 5 seconds to forma a condensed-plasma zone on the interior surface of the container. A further condensed-plasma zone is generated with the original rate of TMDSO and oxygen at 20 sccm with an applied microwave power of 100 W for 4 seconds which generates an additional zone. A clear colorless condensed-plasma coating on the interior surface of the container results with uniform good transmission barrier properties comparable to Example 2.

Example 8b—Three zone coating with Trimethylsilane (TMS)

A three-dimensional beverage container is placed in a vacuum chamber with a microwave-frequency plasma generating sources. The plasma system is designed to generate a plasma substantially in the interior volume of the container. An organosilane reactant gas of trimethysilane (TMS) was admitted to the container at the rate of 2 sccm. Plasma is generated with an applied microwave power of 50 W for 4 seconds generating a condensed-plasma on the interior surface of the container. A second condensed-plasma zone is formed by adding oxygen at 2 sccm to the container with an applied microwave power of 100 W for 10 seconds to form a condensed-plasma zone on the interior surface of the container. A further condensed-plasma zone is generated with the original rate of TMS and oxygen at 20 sccm with an applied microwave power of 120 W for 8 seconds which generates an additional zone. A clear colorless condensed-plasma coating on the interior surface of the container results with uniform good transmission barrier properties comparable to Example 2.

Example 8c—Similar to Example 8a but having only two zones similar to the first and last

A three-dimensional beverage container is placed in a vacuum chamber with a microwave-frequency plasma generating source. The plasma system is designed to generate a plasma substantially in the interior volume of the container. An organosilane reactant gas of tetramethyldisiloxane (TMDSO) is admitted to the container at the rate of 2 sccm. Plasma is generated with an applied microwave power of 100 W for 2 seconds generating a condensed-plasma on the interior surface of the container. A second condensed-plasma zone is formed by adding oxygen at 20 sccm to the container with an applied microwave power of 100 W for 4 seconds to form a condensed-plasma zone on the interior surface of the container. A clear colorless condensed-plasma coating on the interior surface of the container results with uniform good transmission barrier properties comparable to Example 2.

Example 8d—Similar to Example 8a but having only two zones similar to the second and last

A three-dimensional beverage container is placed in a vacuum changer with a microwave generating source. The plasma system is designed to generate a plasma substantially in the interior volume of the container. An organosilane reactant gas of tetramethyldisiloxane (TMDSO) is admitted to the container at the rate of 2 sccm and oxygen was admitted to the container at a rate of 2 sccm. Plasma is generated with an applied microwave power of 100 W for 2 seconds, generating a condensed-plasma on the interior surface of the container. A second condensed-plasma zone is formed by admitting oxygen at 20 sccm to the container with an applied microwave power of 100 W for 4 seconds to form a condensed-plasma zone on the interior surface of the container. A clear colorless condensed-plasma coating on the interior surface of the container results with uniform good transmission barrier properties comparable to Example 2.

Example 8e—Continuous compositional gradient coating

A three-dimensional beverage container is placed in a vacuum chamber with a microwave-frequency generating source. The plasma system is designed to generate a plasma substantially in the interior surface of the container. An organosilane reactant gas of tetramethyldisiloxane (TMDSO) is admitted to the container at the rate of 2 sccm. Plasma is generated with an applied microwave power of 50 W for about 1 second generating a condensed-plasma on the interior surface of the container. Oxygen is then admitted to the container at an initial rate of 2 sccm and is continuously increased to a rate of 20 sccm over a period of 15 seconds. During this oxygen increase period, the microwave power is continuously increased from an initial power of 50 W to a final power of 100 W. The final power and flow conditions are held constant for an additional 2 seconds. A clear colorless condensed-plasma coating on the interior surface of the container results with uniform good transmission barrier properties comparable to Example 2.

### Example 9

A 150 μm thick high-density polyethylene (HDPE) film under vacuum conditions and electrode structure as in Example 1 was exposed to a plasma using O₂ as the plasma generating gas at 35 sccm. Plasma was generated by a load power of 750 watts for 25 seconds with a power density of 9×10⁸ J/kg applied. A condensed-plasma layer was then formed by flowing O₂ at 35 sccm to the vacuum chamber. TMDSO was flowed from 26 sccm to 56 sccm linearly over 3 minutes, then held constant for 15 minutes. The power density was 1.2×10⁸ J/kg. A further condensed-plasma layer was generated with TMDSO at 7.5 sccm and O₂ at 200 sccm with a plasma power of 1500 watts for 4 minutes. The power density of this last step was 1.4×10⁸ J/kg. A colorless and clear condensed-plasma coating with a thickness of 2 microns resulted on the substrate.

Uncoated and condensed-plasma coated HDPE films were characterized for organic compound transmission. The test cell consists of a flow through stainless steel bottom chamber and a glass upper chamber to hold the permeant liquid. The bottom chamber has an internal diameter of 1-inch (0.7 cc internal volume). The film is placed on top of a teflon O-ring to seal the edges and form a barrier between the upper and lower chambers of the cell. For these experiments, 6 mL of CM-15 (15/42.5/42.5 MeOH/isooctane/toluene) was pipetted into the upper chamber and dry nitrogen was used as the sweep gas at a flow rate of 10.0 mL/min. through the bottom chamber of the cell. The nitrogen stream, controlled with a Porter flow controller, passed through the cell and was vented through a glass tee with a septum port. The permeant is monitored by sampling the vapor stream from the septum port using an HP/MTI Analytical Instruments microchip gas chromatograph with an internal sampling pump. A 3 or 4-minute sampling interval was used. Transmission measurements were obtained until the sample exhibited steady-state transmission which required up to 4,000 minutes.

Before each permeation experiment a ˜1.5″ square piece was cut from the polymer film sample. The thickness of the sample was measured with a Mitoyo digital micrometer, averaging 10 readings at different spots on the film. Before and after each permeation test the room temperature and N2 flow through the cell was measured.

Transmission results measured at 24° C. are shown in the table below.

| | | Steady state |
|---|---|---|
| | Organic | Transmission Rate |
| Sample | Compound | (g/m²-day) |
| Uncoated | toluene | 311 |
| HDPE | methanol | 35 |
| | isooctane | 54 |
| | Total | 400 |
| Coated HDPE | toluene | 39 |
| | methanol | 7 |
| | isooctane | 6 |
| | Total | 52 |

### Example 10

On cleaned PET film a coating is generated using vacuum equipment as in Example 1. A condensed-plasma coating having substantially continuously graded structure (as opposed to discreet layers) is formed by flowing an organosilane reactant gas of tetramethyldisiloxane (TMDSO) at an initial rate of 15 sccm. Plasma is generated with an initial application of 800W of load power. After 15 seconds, oxygen is introduced into the chamber an initial flow rate of 0.01 sccm and is increased in a linear fashion to 40 sccm over a period of about 40 minutes. During the oxygen ramp period TMDSO flow is increased from 15 to 45 sccm. These conditions are maintained for 20 minutes. The flow rate of oxygen is then increased from 40 sccm to 200 sccm in a substantially exponential rainp over a period of about 10 minutes. During this period the TMDSO flow is decreased exponentially from 45 sccm to 15 sccm. A corresponding exponential increase to the plasma load power from 800W to 2,700W is performed during this time period. These conditions are maintained for 2 minutes. A clear, colorless, condensed-plasma coating on the PET substrate results with uniform good barrier properties comparable to Example 2.

### Example 11

Utilizing a substrate of polycarbonate a coating of the invention may be prepared in a vacuum chamber under base-vacuum conditions of 0.5 mTorr. The polycarbonate substrate has a thickness of 178 μm (0.007 inch) is located midway between parallel unbalanced magnetron electrodes. The magnetron electrodes as described in U.S. Pat. No. 5,900,284 at a distance of 26.7 cm (10.5 inch) are excited at 110 kHz. In a chamber of cubic configuration having a dimension approximately 0.91 m (3 feet) initially a coating is deposited from a plasma generated at a power of 750 Watts of 1 minute duration from a vapor of tetramethyldisiloxane (TMDSO) of 26 standard cubic centimeters (sccm) (tie layer). Subsequently the flow rate of TMDSO is doubled to 52 sccm to which is added 30 sccm of oxygen as a plasma is generated for 15 minutes at a power of 800 Watts (buffer layer). The sample having a condensed plasma coating thereon is evaluated for oxygen transmission.

### Example 12

A plasma coating is generated according to Example 11. Following the generation of plasma for 15 minutes according to Example 11, the flow rate of TMDSO is reduced to 7 sccm and the flow rate of oxygen is increased to 200 sccm while maintaining the plasma power at 800 Watts for 3.5 minutes (barrier layer). The sample having a condensed-plasma coating thereon is evaluated for oxygen transmission.

### Example 13

Utilizing a comparable substrate of polycarbonate having a thickness of 178 μm (0.007 inch) located midway between parallel unbalanced magnetron electrodes as described in U.S. Pat. No. 5,900,284 at a distance of 26.7 cm (10.5 inch) the electrodes are excited at 110 kHz. A condensed-plasma coating was deposited from a plasma generated at a power of 750 Watts for 1 minute duration from a vapor of TMDSO of 26 (sccm) (tie layer). Subsequently, the flow rate of TMDSO was reduced to 7 sccm and oxygen was added at a flow rate of 200 sccm with a corresponding power change to 800 Watts (barrier layer). A plasma was generated under such conditions for 3.5 minutes. The sample having a condensed-plasma coating thereon was evaluated for oxygen transmission.

| | Oxygen transmission rate | |
|---|---|---|
| | cc/m².day.atm | (cc/100².day.atm) |
| Control - uncoated | 345 (23) | |
| polycarbonate | | |
| Example 11 - tie layer and | 345 (23) | |
| buffer layer | | |
| Example 12 - tie layer, buffer | 0.09 (0.006) | |
| layer and gas barrier layer | | |
| Example 13 - tie layer and | 2.1 | (0.145) |
| gas barrier layer | | |

What claimed is:

1. A polymeric substrate having a barrier coating comprising
a. a polymeric substrate;
b. a first condensed plasma zone of SiOxCyHz, wherein x is from 1.0 to 2.4, y is from 0.2 to 2.4, and z is from zero to 4, on the polymeric substrate wherein the plasma is generated from an organosilane compound in an oxidizing atmosphere; and
c. a further condensed plasma zone of SiOx on the polymeric substrate wherein the plasma is generated from an organosilane in an oxidizing atmosphere sufficient to form the SiOx.

2. A polymeric substrate of claim 1 in which a tie zone for the first condensed plasma zone of (c) to the polymeric substrate is generated from a plasma of an organosilane in a substantially non-oxidizing atmosphere.

3. A polymeric substrate having a barrier coating comprising
a. a plasma deposited zone of an organosilicon compound on the substrate wherein the plasma is generated in a substantially non-oxidizing atmosphere; and
b. a further condensed plasma zone of SiOx on the polymeric substrate wherein the plasma is generated from an organosilane in an oxidizing atmosphere sufficient to form the SiOx.

4. A polymeric substrate having a barrier coating of claim 1, claim 2, or claim 3 comprising a polymeric substrate immediately placed in a vacuum subsequent to being heated and stretched.

5. The polymeric substrate having a barrier coating of claim 1, claim 2 or claim 3 wherein the polymeric substrate is configured in the form of a container.

6. The polymeric substrate having a barrier coating of claim 1, claim 2 or claim 3 wherein the polymeric substrate comprises a recycled polymer.

7. The polymeric substrate having a barrier coating of claim 1, claim 2 or claim 3 wherein the polymeric substrate comprises a polymer recycled from a polymeric substrate having thereon a previous barrier coating.

8. The polymeric substrate having a barrier coating of claim 1, claim 2 or claim 3 wherein the polymeric substrate comprises a polymer recycled from a polymeric substrate having thereon a previous barrier coating prepared according to claim 1, claim 2 or claim 3.

9. A polymeric substrate of claim 1, claim 2 or claim 3 having a barrier coating which provides a barrier to transmission of organic compounds when compared to the uncoated polymeric substrate.

10. A polymeric substrate in which the substrate is a polyolefin and having a barrier coating of claim 1, claim 2 or claim 3.

11. A polymeric substrate of claim 1 in which the substrate is polycarbonate and having a barrier coating of claim 1, claim 2 or claim 3.

12. A process for preparing a barrier coating according to any of claims 1, 2 or 3 on a container comprising depositing one or more barrier coatings within the container using magnetic guidance, or a plasma generating electrode, or both magnetic guidance and a plasma generating electrode.
